(19) United States
(12) Patent Application Publication
(10) Pub. No.: US 2013/0182738 A1
(43) Pub. Date: Jul. 18, 2013

(54) Wavelength-Convertible Semiconductor Laser Which is Driven By Pulse

(71) Applicant: Jeong Soo Kim, Chungcehongnam-do (KR)

(72) Inventor: Jeong Soo Kim, Chungcehongnam-do (KR)

(73) Assignee: Phovel Co., Ltd., Gwangji-si (KR)

(21) Appl. No.: 13/876,732

(22) PCT Filed: Sep. 28, 2011
(86) PCT No.: PCT/KR2011/007120

§ 371 Date: Mar. 28, 2013

(30) Foreign Application Priority Data
Sep. 29, 2010 (KR) 10-2010-0094041

(51) Int. Cl. H01S 5/00

(52) U.S. Cl. CPC H01S 5/0078
USPC 372/75

(57) ABSTRACT

The present invention relates w a wavelength-convertible semiconductor laser which is driven by a pulse, and more specifically, to a wavelength-convertible semiconductor laser, wherein: an expanded resonator is formed by including a laser diode chip on the outside of a pump semiconductor laser diode chip; and an oscillating wavelength of a pump laser is driven by a pulse determined from the outside of the semiconductor laser diode chip by inserting a filter, which is capable of selecting a wavelength, on the inside of said expanded resonator.

### CROSS-REFERENCE TO RELATED APPLICATION

This application claims the benefit of Korean Patent Application No. 10-2010-0094041, filed on Sep. 29, 2010 in the Korean Intellectual Property Office, the disclosure of which is incorporated herein by reference.

### TECHNICAL FIELD

The present invention relates to a wavelength-convertible semiconductor laser which is driven by pulse, and the wavelength-convertible semiconductor laser uses a semiconductor laser as a pumping light source and is driven by a second higher harmonics.

### BACKGROUND ART

Generally, development of a Laser Projection display LPD, which uses laser beams corresponding to the three primary colors including a red color, a green color and a blue color, is actively conducted.

Among the existing displays, the LPD has the highest excellent characteristic in color reproducibility, and has an advantage that a display device with a small screen can be manufactured by using the LPD.

In particular, the LPD has an advantage that a focus alignment depending on a length with respect to a screen is not needed.

The laser beams corresponding to the three primary colors including a red color, a green color and a blue color is needed so as to manufacture a LPD. Among the laser beams, each of the red laser beam and the blue laser beam has been realized by using a single semiconductor chip. However, the green laser beam, which configures the three primary colors and has a wavelength of 532 nm, has not yet realized by using a single semiconductor chip.

The green laser beam with a wavelength of 532 nm v is realized by using a wavelength changing method. The wavelength changing method uses the principle that when original light passes through a crystalline structure with a nonlinear optical characteristic, light with a frequency, which is two times greater than a frequency of the original light, is generated.

The above-described method is a frequency doubling method. The meaning that a frequency becomes two times denotes that a wavelength becomes ½ times. Therefore, to make a green light source of 532 nm by using the frequency doubling method, a laser diode with a wavelength of 1064 nm is needed. first, and a crystalline structure with a nonlinear optical medium, which doubles a frequency of the laser diode, is needed.

The nonlinear optical medium may be, for example, Kotassium Titanyl Phosphate KTP or Lithium Niobate LN, any crystal with nonlinear optical characteristic may be used as a wave changing crystal.

FIG. 1 is an exemplary diagram showing a relation between a current injected to a general semiconductor laser diode and a light output.

As shown in FIG. 1, in the case of a general semiconductor laser diode, a light output is not generated until an injection current becomes approximately 100 mA, and after 100 mA, a light output increases depending on an injected current.

In FIG. 1, a dot line is an imaginary line showing that, the light output is not proportional to a current.

In the case of the semiconductor laser diode described in the embodiment, the light output linearly increases depending on a current, in a driving current section between approximately 100 mA and 400 mA, and slope efficiency, which is a rate of a current increasing quantity to a light-output increase quantity, decrease in a driving current section after 400 mA.

The reason of the characteristic is because the temperature of a laser-oscillation active area of a laser diode chip increases depending on an increase of a laser diode current injection quantity and thus a gain in the laser-oscillation active area decrease. This phenomenon is referred to as a Thermal-rollover.

To prevent the temperature in the active area of the laser diode chip from increasing, a pulse injection method injecting as very short pulse type of current is useful, and particularly, it is well known that the driving of a short pulse equal to or lower than 1 microsecond is effective.

The laser diode chip shown in FIG. 1 has an oscillation threshold current of approximately 100 mA. Therefore, in terms of a light output, an electric power corresponding to an oscillation threshold current is only operated as a loss, in the electric powers applied to the laser diode chip.

A method of reducing a volume of an active area of the laser diode chip is used so as to decrease the oscillation threshold current. However, in this case, an injected current is cornered into a narrow active area, and the thermal-rollover phenomenon described with reference to FIG. 1 occurs in a lower current region. Thus, it is difficult to make a high-power laser diode chip.

Therefore, a high-power pump semiconductor laser is needed so as to make a high-power green laser beam, and if a volume of the active area of the semiconductor laser diode chip is increased so as to get a high power, a threshold oscillation current increases, and thus, an electrical consumption power, which does not contribute to the green light, increases.

Moreover, in the case of a general Fabry-Perot type of laser, a change of an oscillation laser wavelength by a temperature of the laser oscillation active area occurs depending on an amount of a current injected to the semiconductor laser, and also, a change of a wavelength by a change of a refractive index of the semiconductor depending on an injected current concentration occurs at the same time.

Therefore, in a frequency doubling type of green laser using a general Fabry-Perot type of laser as a pump laser, a change of a wavelength of the pump laser occurs depending on a change of a refractive index and a change of a temperature of the active area, and thus, an absorption rate of a pump laser is changed in a medium.

Moreover, in case of using a general Fabry-Perot type of pump laser, a consumption power corresponding to the oscillation threshold current does not contribute to the generation of the green laser beam, and thus, a consumption power for generating the green laser beam increase.

To decrease the threshold current of the semiconductor pump laser, it is needed to reduce a volume of the active area of the semiconductor laser. However, in this case, the thermal-rollover phenomenon is intensified, and thus, a high-power pump laser cannot be manufactured.

### DISCLOSURE OF INVENTION

Accordingly, an aspect of the present invention is directed to provide a wavelength-convertible semiconductor laser which is driven by pulse.

Moreover, another aspect of the present invention is directed to provide a wavelength-convertible semiconductor laser, a pulse period of which is equal to or lower than 5 Microsecond.

Moreover, another aspect of the present invention is directed to provide a wavelength-convertible semiconductor laser, which minimizes a consumption power depending on an oscillation threshold current of a pump laser and has a high efficiency of a green laser oscillation type in a wide driving temperature condition at the same time.

Moreover, another aspect of the present invention is directed to provide a wavelength-convertible semiconductor laser, which generates a green laser beam having a high electric light change efficiency for the wide green laser output condition of a several mW class to a several hundreds mW class.

To achieve these and other advantage and in accordance with the purpose of the invention, as embodied and broadly described herein, there is provided as wavelength-convertible semiconductor laser which is driven by pulse, wherein, a resonator expanded into a shape including a laser diode chip is provided in an outside of a semiconductor laser diode chip for pumping, a filter enable to select a wavelength is inserted into an inside of the expanded resonator, and thus, an oscillation wavelength of a pump laser is determined in an outside of the semiconductor laser diode chip.

In the wavelength-convertible semiconductor laser which is driven by pulse, a current, which has a pulse period equal to or lower than 5 microsecond and is formed in a short pulse type, is injected into the pump laser.

In the wavelength-convertible semiconductor laser which is driven by pulse, the semiconductor laser includes a first medium absorbing a laser light, which passes through the filter and has a wavelength of near 808 nm, to convert the laser light to a laser light with a wavelength of 1064 nm; and a second medium doubling, a frequency of the laser light with a wavelength of 1064 nm to convert the laser light to a laser light with a wavelength of 532 nm.

In the wavelength-convertible Semiconductor laser which is driven by pulse, the first medium includes Nd:YVO4, and the second medium includes KTP.

In the wavelength-convertible semiconductor laser which is driven by pulse, the semiconductor laser further includes a first lens part collimating a light generated through the semiconductor laser diode chip to transfer the light to the filter; and a second lens part directing a light passes through the filter 230 to the Nd:YVO4.

In the wavelength-convertible semiconductor laser which is driven by pulse, a cleavage plane facing the filter of the semiconductor laser diode chip is coated by using a non-reflective coating.

In the wavelength-convertible semiconductor laser which is driven by pulse, the filter is configured with a Volume Bragg grating or an etalon filter type.

### ADVANTAGEOUS EFFECTS

According to the characteristic of the present invention, in a wavelength-convertible semiconductor laser of the present invention using a semiconductor laser as a pumping light source, there is no change of a wavelength depending on a change of an operation temperature of a semiconductor laser, and there is no change of a wavelength and no deterioration of a light output efficiency depending on the intensity of a current driving a semiconductor laser, and thus, a light efficiency of a wavelength-convertible semiconductor laser using a second higher harmonics may increase.

### BRIEF DESCRIPTION OF DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1 is an exemplary diagram showing a relation between a current injected to a general semiconductor laser diode and a light output;

FIG. 2 is an exemplary diagram illustrating a wavelength-convertible semiconductor laser which is driven by pulse according to an embodiment of the present invention;

FIG. 3 is an exemplary diagram showing a gain spectrum of a laser diode chip with respect to an injected current when a cleavage plane, in which a laser output occurs in a semiconductor laser diode chip according to an embodiment of the present invention, is coated by using a non-reflective coating;

FIG. 4 is an exemplary diagram showing a time-based output of a green laser of 532 nm, which is realized by using a semiconductor laser of 808 nm as a pumping light source and using a frequency doubling method of Nd:YVO4 and KTP;

FIGS. 5 to 8 are exemplary diagrams showing time-based output patterns of a green laser when a semiconductor laser is being driven with a period, which is a period of a current driving, a semiconductor laser of 808 nm and is equal to or lower than 5 microsecond; and

FIG. 9 is an exemplary graph showing a relation between a pulse width and an intensity of an output laser depending on the pulse width during driving a semiconductor laser with a pulse.

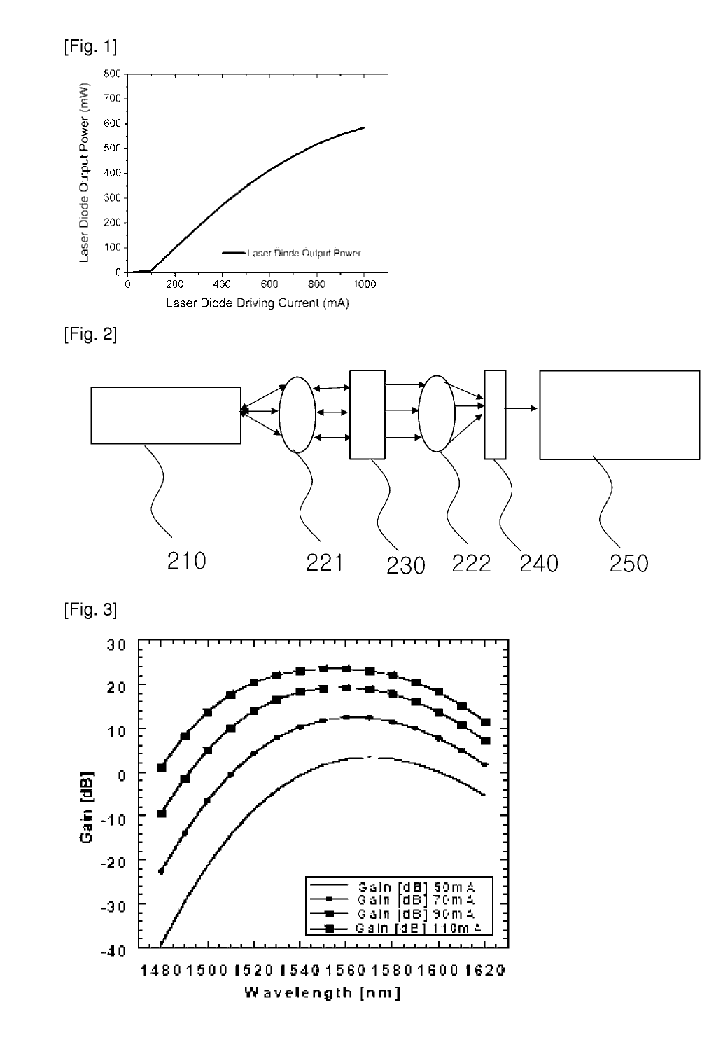

### BEST MODES FOR CARRYING OUT THE INVENTION

The configuration of the present invention is divided into two parts, that is, a hardware part and a method part. In the hardware part of the present invention, a resonator expanded into a shape including a laser diode chip is provided in an outside of a semiconductor laser diode chip for pumping, a filter enable to select a wavelength is inserted into the inside of the expanded resonator, and thus, an oscillation wavelength of a pump laser is determined in an outside of a semiconductor laser diode chip. In the method part, a current, which has a pulse period equal to or lower than 5 microsecond and is formed in a very short pulse type, is injected into the pump laser configured as described above.

Reference will now be made in detail to the exemplary embodiments of the present invention, examples of which are illustrated in the accompanying drawings. Wherever possible, the same reference numbers will be used throughout the drawings to refer to the same or like parts. Hereinafter, embodiments of the present invention will be described in detail with reference to the accompanying drawings.

FIG. 2 is an exemplary diagram illustrating a wavelength-convertible semiconductor laser which is driven by pulse according to an embodiment of the present invention.

As shown in FIG. 2, an embodiment of the present invention includes a semiconductor diode chip 210, a first lens part 221, a filter 230, a second lens part 222, a first medium 240 and a second medium 250.

The semiconductor laser diode chip 210 for pumping emits a laser light. Here, a cleavage plane facing the filter 230 of the semiconductor laser diode chip 210 is coated by using a non-reflective coating, and thus, a Fabry-Perot mode oscillation by the cleavage plane of the semiconductor laser diode chip 210 is suppressed. Therefore, if a current is flowed to the semiconductor laser diode chip 210 when the Fabry-Perot mode oscillation by a resonator of the semiconductor laser diode chip 210 itself is being suppressed, a voluntarily emitted light starts to be emitted through the cleavage plane.

The first lens part 221 collimates the light generated through the cleavage of the semiconductor laser diode chip 210 to transfer the light to the filter 230.

The filter 230 selectively reflects some of the laser light emitted from the semiconductor laser diode chip 210 and passes sonic of the laser light.

In this case, a light, which is reflected by the filter 230 and has a specific wavelength, turns back along a progress path.

The second lens part 222 directs the remaining light, which reaches the filter 230 to pass through the filter 230, to Nd:YVO4 240.

In this case, the first lens part 221 and the second lens part 222 may be configured with one of a spherical lens, an aspherical lens and a cylinder type lens.

The first medium 240 absorbs a light, which passes through the filter 230 and has a wavelength of near 808 nm, to convert the laser light to a laser light with a wavelength of 1064 nm.

Here, the first medium includes Nd:YVO4, or may be a medium having a characteristic similar to the Nd:YVO4.

The second medium 250 doubles the frequency of the laser light with a wavelength of 1064 nm to convert the laser light to a laser light with a wavelength of 532 nm.

The second medium 250 includes KTP, or may be a medium having a characteristic similar to the KTP.

The filter 230 is a wavelength-selective filter, may be a Volume bragg grating type of wavelength-selective filter, and may be a wavelength-selective filter of an etalon filter.

The Volume bragg grating type filter or the etalon filter type filter 230 may be a substrate such as a glass, and the filter has a characteristic that a change of a selective wavelength depending on a temperature is very small.

That is, a filter used in an expanded resonator type of laser as like the embodiment of the present invention is changed about 0.01 nm/° C. in a wavelength. In the expanded resonator type of semiconductor, a pump laser may be manufactured so as to have a wavelength of 808 nm±1.5 nm in a temperature section of 300° C., and thus, the first medium 240 can be virtually and efficiently pumped in every temperature.

In the fact that the expanded resonator has the using temperature section of 300°C., a wavelength, which can be selected by a filter, is only considered. Therefore, in order for the semiconductor laser diode chip to oscillate, an oscillation wavelength is determined by using the competition between a gain considering a feedback in a feedback wavelength, as well as a feedback of a laser light, and a gain peak of a laser diode itself.

FIG. 3 is an exemplary diagram showing a gain spectrum of a laser diode chip with respect to an injected current when a cleavage plane, in which a laser output occurs in a semiconductor laser diode chip according to an embodiment of the present invention, is coated by using a non-reflective coating.

As shown in FIG. 3, a gain spectrum of a semiconductor laser diode has a more gentle slope in a high injected current condition.

Therefore, to set an oscillation wavelength of a semiconductor laser in a wide temperature range by using a wavelength fed back in an outside of a laser diode chip, if possible, it is good to drive a semiconductor laser in a high injected current condition.

In this case, if an injected current injected to a semiconductor laser diode simply becomes greater, a wavelength of a semiconductor laser diode chip can be set in a wide temperature range. However, a problem that an output of a semiconductor laser diode chip also becomes greater occurs.

This problem can be solved. That is, an average light output can be controlled by driving a pump laser with a pulse and adjusting a pulse width, without changing a value of a driving current peak of a pump laser.

In a method of realizing a green laser with a wavelength of 532 nm by using a frequency doubling method, in which a semiconductor laser of 808 nm band is used as a pump light source and Nd:YVO4 and KTP are used, when a laser of 808 nm is driven with a pulse, a green laser is driven by generally using a pulse pattern having a pulse width equal to or more than 1 millisec.

The reason is as below. That is, when the first medium absorbs a laser of 808 nm to generate a laser light of 1064 nm, a transition of electrons from a 808 nm absorption state to 1064 nm state has to occur in the first medium, and in this case, a lifetime of the transition from a 808 nm state 0 1064 nm state takes approximately 50 microsecond.

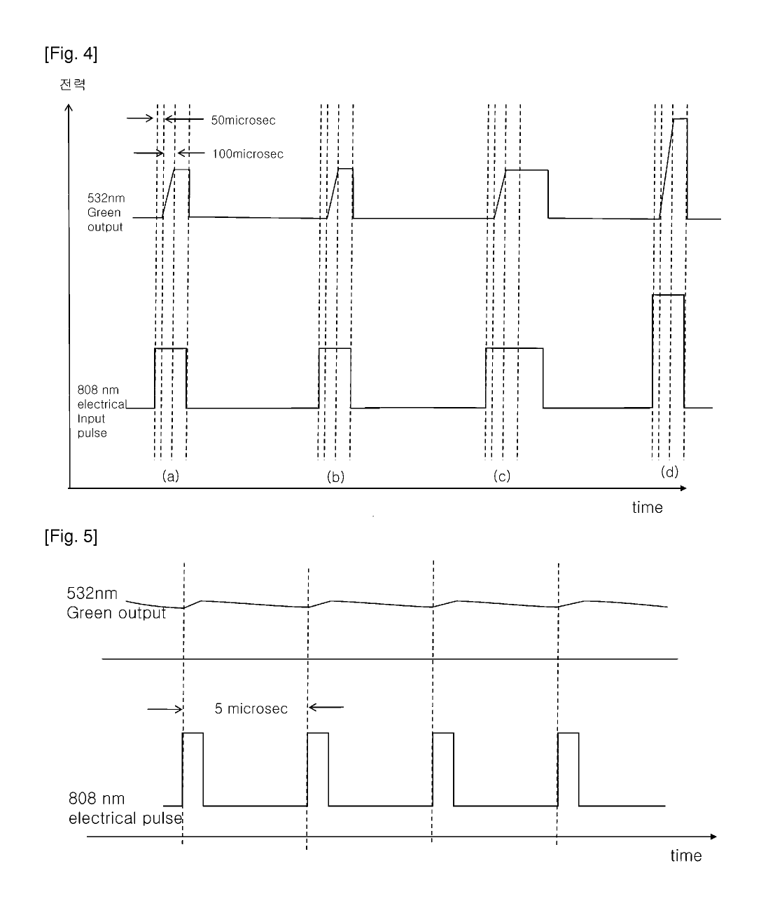

FIG. 4 is an exemplary diagram showing a time-based output of a green laser of 532 nm, which is realized by using a semiconductor laser of 808 nm as a pumping light source and using, a frequency doubling method of a first medium and a second medium.

As shown in FIG. 4, a portion (a) and a portion (b) of FIG. 4 are exemplary diagrams showing waveforms of a green light output when input current pulses haying the same waveforms are applied, a portion (c) is an exemplary diagram showing output waveform of a green light When a value of a peak power of a pump laser diode of 808 nm is the same as that of a portion (b) of FIG. 4 but a pulse width is longer than that of a portion (b) of FIG. 4, and a portion (d) is an exemplary diagram showing output waveform of a green light when a pulse width is the same as that of a portion (a) of FIG. 4 but a value of a peak power of an input power is greater than that a portion (a) of FIG. 4.

In the case of a portion (a) and a portion (1) of FIG. 4, if a current for driving a semiconductor laser diode chip of 808 nm flows, after delay times corresponding to about 50 microsecond, a green laser having a wavelength of 532 nm starts to be output, and an output of the green laser increases for about 100 microsecond.

Therefore, in the case of a portion (a) and a portion (b) of FIG. 4, after a current applied to a pump laser of 808 nm starts to be inputted, and then, a time about 150 microsecond elapses, a stable green laser starts to be output.

In the case of a portion (c) of FIG. 4, a pulse width of an input power is greater than that of a portion (a) and a portion (b) of FIG. 4. Here, a value of a peak of an output power of 532 nm is the same as that of a portion (a) and a portion (b) of FIG. 4, but an output is continuously outputted for a time longer than that of a portion (a) and a portion (b) of FIG. 4.

In the case of a portion (d) of FIG. 4, a continuous time of an output power of 532 nm is the same as that of a portion (a) and a portion (b) of FIG. 4, but a value of a peak power of an output with 532 nm increases depending on an increase of a input power.

In the green laser, which is configured with a pump laser with a wavelength of 808 nm, a first medium and a second medium and has a wavelength of 532 nm, when a driving pulse driving a pump laser of 808 nm is outputted for a time equal to or more than 150 microsecond, a peak value of an output power of 532 nm is changed depending on a peak value of an input power. That is, a pulse width of an output is determined depending on a pulse width of an input.

Therefore, when a semiconductor laser, which is used as pump laser in a green laser configured as shown in FIG. 2, is driven with an input electricity pulse width of 100 microsecond, an output of a pump laser of 808 nm ends before an output of a green laser sufficiently increase. Therefore, an output of a green laser is very weak in comparison with an input electricity power. In the case shown in FIG. 4, after electricity driving a pump laser for 808 nm is inputted and then, a time about 150 microsecond elapses, an output of a green laser is not relative to a pulse width and a peak output of a green laser only depends on an electric input for driving with 808 nm.

FIGS. 5 to 8 are exemplary diagrams showing time-based output patterns of a green laser when a semiconductor laser is being driven with a period, which is a period of a current driving a semiconductor laser of 808 nm and is equal to or lower than 5 microsecond.

As shown in FIGS. 5 to 8, an average input power inputted to a semiconductor laser of 808 nm is shown with a duty ratio of on/off time of a pulse and a power of a pulse. In the case shown in FIG. 5, an output of a green laser is outputted with a characteristic almost like CW, and a peak output of a green laser is a function of a peak input of an input power for driving with 808 nm and a duty ratio.

In the case shown in FIG. 4, when a pulse width driving a semiconductor laser of 808 nm is equal to or more than 150 microsecond, a peak output of a green laser, which is outputted after a green light output becomes stable, is not relative to a pulse period of an input electricity signal for driving a semiconductor of 808 nm or the like, and only depends on a peak input power of an input electricity signal. On the other hands, as shown in FIG. 5, when a semiconductor laser is driven such that a semiconductor has a very short pulse period, a peak output of a green laser also depends on a peak input power for driving a semiconductor laser of 808 nm and a duty ratio of a pulse.

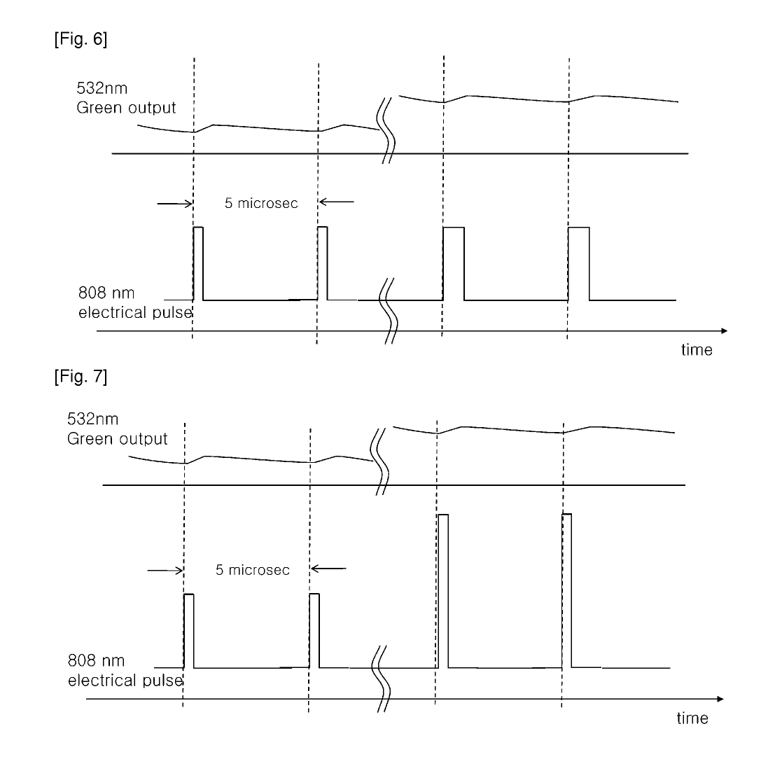

As shown in FIG. 6, if a pulse width of an electricity input signal is only changed when a value of an electricity input power is being fixed, an intensity of a peak output of an output green light increases or decreases in proportion to a pulse width.

FIG. 7 shows that if a peak power of an input electricity is changed when a pulse width of an input electricity is being fixed, an intensity of an output peak of a green laser is changed.

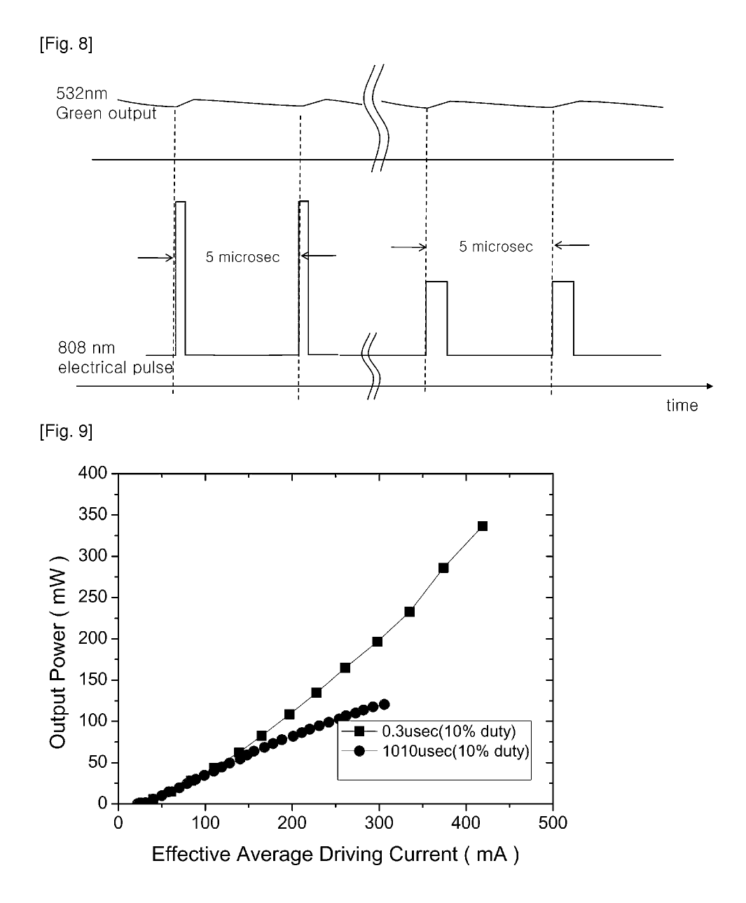

FIG. 8 shows that if a pulse width of an input electricity power and a value of a peak power of an input electricity power are properly controlled, a constant peak output of a green light can be obtained independent on a pulse width and a value of a peak power of an input electricity.

FIG. 9 is an exemplary graph showing a relation between a pulse width and an intensity of an output laser depending on the pulse width during driving a semiconductor laser with a pulse.

FIG. 9 shows a light output of 808 nm when a pump laser of 808 nm is driven by using an electricity power pulse which has a pulse width of 0.3 microsecond (μs) and a duty ratio of 10%, and a light output of 808 nm when a pump laser of 804 nm is driven by using an electricity power pulse which has a pulse width of 1010 microsecond (μs) and a duty ratio of 10%,

When a pulse width is 1010 microsecond (μs), if a driving current exceeds 150 mA, an increase of a light output is saturated.

On the other hand, when a pulse width is 0.3 microsecond (μs) a light output does not decrease depending on an increase of an input current.

However, this increase of a light output only means an increase of an intensity of a light output, and thus, the increase of a light output of 808 nm does not cause an increase of a green light output

The reason is because if a current is increased so as to increase a light output, a wavelength of a semiconductor laser is changed.

Therefore, even though a Fabry-Perot type of pump laser of 808 nm is driven with a short pulse such as 0.3 microsecond, a wavelength of 808 nm band is converted to another wavelength, and thus, a phenomenon that a green light output rather decreases occurs.

Moreover, when an outer resonator type of pump laser having an oscillation wavelength of 808 nm is manufactured, and a pump laser, in which an oscillation wavelength is fixed independent on a current injected to a semiconductor laser, is used, an oscillation wavelength is fixed independent on an intensity of a driving current of a pump laser of 808 nm. Therefore, even though a semiconductor laser is driven with a pulse, an oscillation wavelength is fixed independent on a pulse width or a pulse period, and thus, the pump laser operates as a pump laser proper to a green light source.

However, because a transition lifetime between an absorption state absorbing a wavelength of 808 nm in a first medium and an emission state emitting a wavelength of 1064 is about several tens microsecond, if a pulse width of an electricity input pulse width decreases within 100 microsecond when a wavelength of a pump laser of 808 nm is being fixed by using an outer resonator, a first medium does not follow a flickering of a pump laser of 808 nm sufficiently. Therefore, an output of 1064 nm decreases, and thus, an output of a green laser of 532 nm decreases.

A first medium equally responds to a light input of 808 nm with a pulse period within 5 microsecond and a light input of 808 nm of CW. Therefore, a decrease of a green light output is suppressed when a light input of 808 nm with a pulse period within 5 microsecond is inputted.

As described above, a characteristic of an oscillation wavelength of a Fabry-Perot type of semiconductor laser is changed depending on an operation temperature of a semiconductor laser, and a wavelength is changed depending on a current injected to a semiconductor laser. Moreover, a semiconductor laser has a characteristic in that an emitting effect decreases due to an increase of a temperature in an active area during injecting a current.

Therefore, when an oscillation wavelength of a pump laser of 808 nm is fixed by using a wavelength selecting device disposed in an outer resonator such that a change of an oscillation wavelength depending on an injected current applied by a pump laser of 808 nm does not occur, and then, a pump laser of 808 nm is driven with as pulse having a pulse period equal to or lower than 5 microsecond, a change of a wavelength of the pump laser of 808 nm depending on an intensity of an electricity power applied to a pump laser of 808 nm does not occur. Also, a change of a wavelength depending on a temperature, in which a pump laser of 808 nm is operated, does not occur, and thus, the pump laser of 808 nm becomes a pump light source, in which an emitting efficiency of 808 nm depending on a current injected to a pump laser of 808 nm does not decrease, and a deterioration of an oscillation performance of 1064 nm depending on a transition lifetime of a first medium does not occur. Therefore, a very efficient green laser can be manufactured.

A pump light source using a method, in which the above-described outer resonator type of pump laser of 808 nm is driven with a pulse period within 5 microsecond, becomes a pump laser, which has the most appropriate configuration for a green laser driven by a second higher harmonics.

In the above-described embodiment of the present invention, a semiconductor laser with a wavelength of 808 nm band, and a green laser of 532 nm formed by a first medium and a second medium have been described as an example, but the above-described embodiment of the present invention may be applied to a semiconductor pumping laser and a wavelength-convertible semiconductor laser which is driven by a second higher harmonics.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A wavelength-convertible semiconductor laser which is driven by pulse, wherein,
a resonator expanded into a shape including a laser diode chip is provided in an outside of a semiconductor laser diode chip for pumping,
a filter enable to select a wavelength is inserted into an inside of the expanded resonator, and thus,
an oscillation wavelength of a pump laser is determined in an outside of the semiconductor laser diode chip.

2. The semiconductor laser of claim 1, wherein,
a current, which has a pulse period equal to or lower than 5 microsecond and is formed in a short pulse type, is injected into the pimp laser.

3. The semiconductor laser of claim 1 comprising:
a first medium absorbing a laser light, which passes through the filter and has a wavelength of near 808 nm, to convert the laser light to a laser light with a wavelength of 1064 nm; and
a second medium doubling a frequency of the laser light with a wavelength of 1064 nm to convert the laser light to a laser light With a wavelength of 532 nm.

4. The semiconductor laser of claim 3, wherein,
the first medium comprises Nd:YVO4, and
the second medium comprises KTP.

5. The semiconductor laser of claim 3 further comprising:
a first lens part collimating a light generated through the semiconductor laser diode chip to transfer the light to the filter; and
a second lens part directing a light passes through the filter 230 to the Nd:YVO4.

6. The semiconductor laser of claim 5, wherein,
a cleavage plane facing the filter of the semiconductor laser diode chip is coated by using a non-reflective coating.

7. The semiconductor laser of claim 3, wherein,
the filter is configured with a Volume Bragg grating or an etalon filter type.
